(19) United States
(12) Patent Application Publication
(10) Pub. No.: US 2021/0105897 A1
(43) Pub. Date: Apr. 8, 2021

(54) Printed Circuit Board for Transmission Control

(71) Applicant: Vitesco Technologies Germany GmbH, Hannover (DE)

(72) Inventors: Johannes Bock, Kirchensittenbach (DE); Markus Heckel, Schwabach (DE)

(73) Assignee: Vitesco Technologies Germany GmbH, Hannover (DE)

(21) Appl. No.: 17/124,896

(22) Filed: Dec. 17, 2020

Related U.S. Application Data
(63) Continuation of application No. PCT/EP2019/062733, filed on May 16, 2019.

(30) Foreign Application Priority Data
Jun. 27, 2018 (DE) 10 2018 210 469.7

(51) Int. Cl. H05K 1/11; H05K 3/42

(52) U.S. Cl. CPC H05K 1/115; H05K 2201/09063; H05K 3/429

(57) ABSTRACT

A printed circuit board for transmission control and for arrangement on an interface is disclosed. The printed circuit board includes an upper side of the printed circuit board and an underside of the printed circuit board. A plurality of spaced-apart conductor tracks arranged at a distance from the upper side of the printed circuit board. The conductor tracks are connected to each other in an electrically conductive manner by way of a first plated-through hole. The first plated-through hole is drilled out on the underside of the printed circuit board in such a way that it is arranged so as to be set back in relation to the underside of the printed circuit board. The printed circuit board is arranged on an interface, the underside of the printed circuit board facing the interface.

### CROSS-REFERENCE TO RELATED APPLICATIONS

This application claims the benefit of International Application PCT/EP2019/062733, filed May 16, 2019, which claims priority to German Application DE 10 2018 210 469.7, filed Jun. 27, 2018. The disclosures of the above applications are incorporated herein by reference.

### TECHNICAL FIELD

The disclosure relates to a printed circuit board used for transmission control.

### BACKGROUND

The use of printed circuit boards used for transmission control is known. In the case of the known printed circuit boards, it is provided that they have a plurality of conductor tracks that are spaced apart from one another. The conductor tracks are connected to one another in an electrically conductive manner by a plated-through hole. It is provided that the plated-through hole is made to extend from the upper side of the circuit board to the underside of the circuit board. Due to the manufacturing process, on the upper side and underside of the circuit board the plated-through hole has a protrusion, which is usually also referred to as a residual ring.

If such a printed circuit board were arranged on an interface in a transmission, the printed circuit board would be connected to the interface in an electrically conductive manner due to the protrusion of the plated-through hole on the underside of the circuit board. This is to be avoided. It is therefore known that an insulating layer, which is also known among other things as a thermal interface, is arranged between the printed circuit board and the interface. Electrical insulation between the printed circuit board and the interface can be provided by means of the thermal interface between the underside of the circuit board and the interface.

Since the printed circuit board is installed in a transmission, and consequently can come into contact in the transmission with various aggressive media, such as for example transmission oil, there is the risk that the thermal interface may break down due to the aggressive media. This has the effect that the adhesive action of the printed circuit board in relation to the interface may be reduced. In addition, the dissolved or detached material of the thermal interface may be distributed in the transmission.

### SUMMARY

The disclosure relates to a transmission control apparatus for a motor vehicle that includes a printed circuit board for transmission control and an interface supporting the printed circuit board. The disclosure also relates to the use of the printed circuit board for transmission control and the interface. In this case, it is provided that a plated-through hole made to extend through the printed circuit board for the electrical connection of the conductor tracks arranged within the printed circuit board is formed as set back in relation to an underside of the circuit board. In this way, when the printed circuit board is arranged on the interface with the underside of the circuit board facing the interface, electrical insulation of the printed circuit board in relation to the interface can be provided in a simple manner due to the set-back formation of the plated-through hole.

Therefore, the disclosure specifies the use of a printed circuit board for transmission control and for arrangement on an interface, where thermal and/or electrical insulation that has increased resistance to media is provided between the printed circuit board and the interface.

Implementations of the disclosure may include one or more of the following optional features. In some implementations, the printed circuit board has between an upper side of the circuit board and an underside of the circuit board arranged at a distance from the upper side of the circuit board a plurality of spaced-apart conductor tracks, which are connected to each other in an electrically conductive manner by way of a first plated-through hole, where the first plated-through hole is drilled out on the underside of the circuit board in such a way that it is arranged so as to be set back in relation to the underside of the circuit board, and the printed circuit board may be arranged on an interface, the underside of the circuit board facing the interface.

In other words, one aspect of the disclosure provides a printed circuit board for transmission control is arranged on an interface. The printed circuit board may be integrated in a transmission, the transmission may be designed for a motor vehicle. In some examples, the printed circuit board is arranged within the transmission as a wiring level, in order to combine both the power areas and the logic areas on one circuit carrier. The interface is arranged in the transmission and is used, among other things, for fastening the printed circuit board.

The printed circuit board has an upper side of the circuit board and an underside of the circuit board, which is arranged at a distance from the upper side of the circuit board. The upper side of the circuit board and the underside of the circuit board may be arranged essentially parallel to one another. A plurality of conductor tracks that are spaced apart from one another are formed and/or arranged between the upper side of the circuit board and the underside of the circuit board. The conductor tracks are connected to one another in an electrically conductive manner by way of a first plated-through hole through the printed circuit board. The first plated-through hole is consequently made to extend from the upper side of the circuit board to the underside of the circuit board. The first plated-through hole is drilled out on the underside of the circuit board. The plated-through hole is therefore formed as set back in relation to the underside of the circuit board.

The printed circuit board is designed to be connected to an interface. It is in this case provided that the underside of the circuit board faces the interface. Due to the drilling out of the plated-through hole, as a result of which the plated-through hole is no longer flush with the underside of the circuit board, but rather is formed as set back, the printed circuit board may be arranged on the interface in an electrically insulating manner. In this way, the use of a printed circuit board for transmission control and for arrangement on an interface is provided, making it possible to dispense with the thermal interface or the insulation material between the printed circuit board and the interface by the first plated-through hole being drilled out on the underside of the circuit board. Since no insulation material is then required, the material costs for using the printed circuit board in a transmission control device for arrangement on an interface can be reduced. In addition, the risk of the insulation material dissolving due to the aggressive media arranged in the transmission can be avoided.

In some implementations, a second plated-through hole is made to extend to the underside of the circuit board and/or has a protrusion in relation to the underside of the circuit board, where the second plated-through hole is connected in an electrically conductive manner to a ground layer arranged within the printed circuit board. It is accordingly provided that the printed circuit board has in addition to the first plated-through hole a second plated-through hole, which is formed from the upper side of the circuit board to the underside of the circuit board. It is then provided that this second plated-through hole on the underside of the circuit board is not drilled out like the first plated-through hole. Consequently, the second plated-through hole is either formed flush with the underside of the circuit board and/or has a protrusion in relation to the underside of the circuit board. The second plated-through hole is only connected in an electrically conductive manner to the ground layer arranged within the printed circuit board. In this way, in the event of a voltage-induced flashover, a discharge can be diverted directly into the ground layer. The voltage-induced flashover is therefore not harmful to the other circuit components of the printed circuit board.

In this context, in some examples, the second plated-through hole has a solder resist layer between the underside of the circuit board and/or the protrusion in relation to the underside of the circuit board and the interface. The solder resist layer is consequently arranged between the second plated-through hole and the interface. The solder resist layer does not have insulation resistance. This means that, as a further consequence of a voltage-induced flashover, a discharge may be diverted directly into the ground layer of the printed circuit board and therefore the risk of damage to the other circuit components of the printed circuit board can be reduced.

In some implementations, it is provided that the first plated-through hole and/or the second plated-through hole are each formed as a sleeve. This has the advantage that the sleeve may be inserted and fixed in a through-hole which extends from the upper side of the circuit board to the underside of the circuit board. An electrically conductive connection between the conductor tracks and the sleeve or between the ground layer and the sleeve can therefore be established in a simple manner.

In principle, the conductor tracks, the first plated-through hole and/or the second plated-through hole may be formed from an electrically conductive material. In some examples, the conductor tracks and/or the first plated-through hole and/or the second plated-through hole are formed from copper or at least comprise copper. By contrast with the other electrically conductive materials, copper has a relatively good and high electrical conductivity and therefore causes low electrical losses. Consequently, the electrical conductivity of the printed circuit board may be increased.

In some implementations, the sleeve is potted with a resin. The sleeve accordingly has a cavity which is enclosed by the sleeve wall lying against the printed circuit board. This cavity is potted with a resin. By filling the cavity of the sleeve, the durability of the sleeve, and therefore the service life of the sleeve, may be increased. In addition, if the printed circuit board is later overmolded or encapsulated, it is possible to avoid plastics material penetrating into the cavity of the sleeve and not completely filling it, but instead voids forming within the cavity of the sleeve. This allows the surface quality to be increased when encapsulating the printed circuit board, which can increase the impermeability of the encapsulation.

In some implementations, it is provided that the printed circuit board is arranged on the interface in a form-fitting, material-bonding and/or force-fitting manner. It is particularly advantageously provided that there is only a form-fitting and/or a force-fitting connection between the printed circuit board and the interface. This has the advantage that, as is the case with a material-bonding connection, it is possible to dispense with adhesives. A material-bonding connection may have the disadvantage that the adhesive could dissolve due to the aggressive media prevailing in the transmission. A force-fitting connection may be a screw connection. In this way, the printed circuit board can be fastened and/or arranged on the interface in a simple manner. Similarly, a clip connection may also be provided for connecting the printed circuit board and the interface.

In principle, the interface may be formed in such a way that it is arranged and/or designed to receive the printed circuit board. An advantageous development of the disclosure is that the interface is a hydraulic block of a transmission.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a section through a printed circuit board which is arranged on an interface, the printed circuit board having first plated-through holes,

FIG. 2 shows a section through a printed circuit board which is arranged on an interface, the printed circuit board having a first plated-through hole and a second plated-through hole.

Like reference symbols in the various drawings indicate like elements.

### DETAILED DESCRIPTION

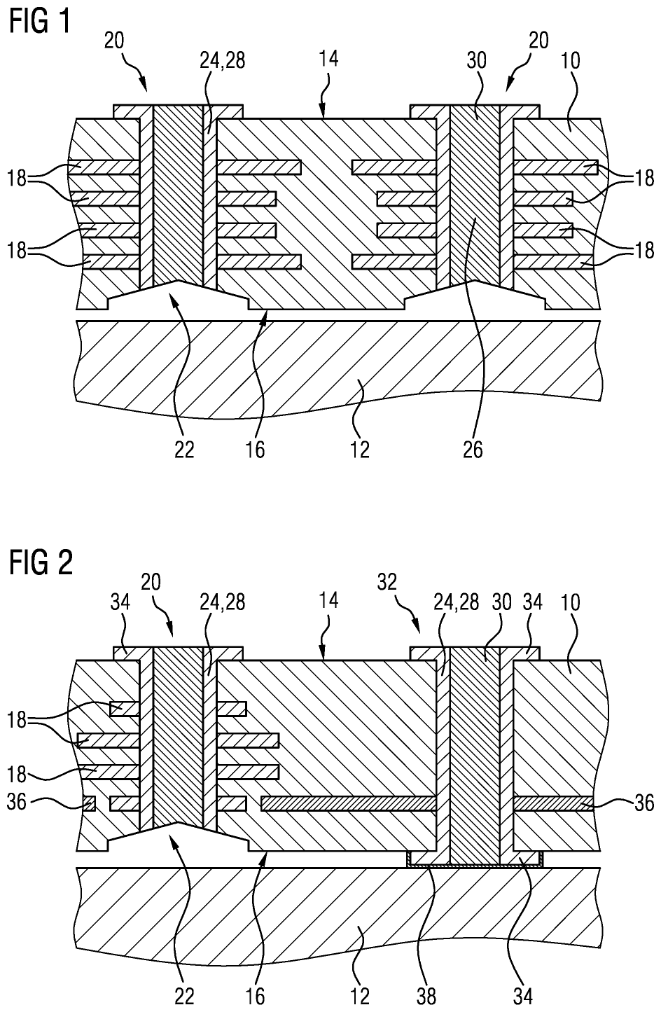

In FIG. 1, a printed circuit board 10 for transmission control and for arrangement on an interface 12 is shown. The printed circuit board 10 has an upper side 14 of the circuit board and an underside 16 of the circuit board, which is arranged at a distance from the upper side 14 of the circuit board. The upper side 14 of the circuit board and the underside 16 of the circuit board are arranged and/or formed essentially parallel to one another. A plurality of conductor tracks 18 arranged spaced apart from one another are arranged between the upper side 14 of the circuit board and the underside 16 of the circuit board 10. The conductor tracks 18 are connected to one another in an electrically conductive manner by way of a first plated-through hole 20, which is made to extend through the printed circuit board 10. The first plated-through hole 20 is drilled out 22 on the underside 16 of the circuit board in such a way that it is formed as set back in relation to the underside 16 of the circuit board 10. The drilling out of the plated-through hole 20 on the underside 16 of the circuit board 10 is also described as “back drilling”. By drilling out the first plated-through hole, manufacturing-related remains of the first plated-through hole near the underside of the circuit board are removed. Consequently, when the printed circuit board 10 is arranged on the interface 12, electrical contacting of the printed circuit board 10 in relation to the interface 12 can be avoided in the area of the first plated-through hole 20.

By contrast with the known prior art, therefore no additional insulation material is required for the electrically conductive insulation of the printed circuit board 10 in relation to the interface 12. Consequently, on the one hand, insulation material between the printed circuit board 10 and the interface 12 can be saved, as a result of which manufacturing costs can be reduced. In addition, the risk of the insulation material dissolving due to the aggressive media arranged in the transmission, such as for example transmission oil, which could contaminate the transmission oil, can be avoided.

In some examples, the first plated-through hole 20 and the conductor tracks 18 are formed from copper. Copper has a high conductivity. Consequently, electrical losses can be reduced.

The first plated-through hole 20 is formed as a sleeve 24. The sleeve 24 has a sleeve cavity 26, which is enclosed at least in sections by the sleeve wall 28 adjoining the printed circuit board 10. The sleeve cavity 26 is potted with a resin 30. By potting the sleeve cavity 26, it is possible to avoid aggressive medium getting into this sleeve 24. In this way, the durability of the sleeve 24 can be increased. In addition, the potting of the sleeve cavity 26 has the advantage that, if the printed circuit board 10 is later encapsulated or overmolded, the overmolding material does not have to laboriously find its way into the cavity of the sleeve 24. In this way, the quality of the encapsulating or overmolding process can be increased.

FIG. 2 shows the printed circuit board 10 known from FIG. 1 for arrangement on the interface 12, where, as a difference from FIG. 1, in FIG. 2 the printed circuit board 10 then has in addition to a first plated-through hole 20 a second plated-through hole 32. The first plated-through hole 20 shown in FIG. 2 is identical to the first plated-through hole 20 shown in FIG. 1. The second plated-through hole 32 is made to extend from the upper side 14 of the circuit board to the underside 16 of the circuit board 10. The second plated-through hole 32 is formed as a sleeve 24. The sleeve 24 has a protrusion 34 respectively on the upper side 14 of the circuit board and the underside 16 of the circuit board. This protrusion 34 is usually a ring due to the manufacturing process that arises when the sleeve 24 is arranged and fixed in the printed circuit board 10. The second plated-through hole 32 is arranged in the printed circuit board 10 in such a way that it is only connected in an electrically conductive manner to a ground layer 36 arranged in the printed circuit board 10.

It can also be seen that a solder resist layer 38 is arranged on the protrusion 34, which protrudes beyond the underside 16 of the circuit board 10, and is therefore arranged between the sleeve 24 and the interface 12. The solder resist layer 38 does not have insulation resistance. Consequently, the second plated-through hole 32 is connected in an electrically conductive manner to the interface 12, while the first plated-through hole 20 is arranged in an electrically conductively insulated manner in relation to the interface 12 as a result of the drilling out 22 in the first plated-through hole 20. Due to the fact that the second plated-through hole 32 is connected to the interface 12 in an electrically conductive manner, in the event of a voltage-induced flashover the discharge can be introduced directly into the ground layer 36. In this way, voltage-induced damage to the further circuit components of the printed circuit board 10 can be reduced and/or avoided.

A number of implementations have been described. Nevertheless, it will be understood that various modifications may be made without departing from the spirit and scope of the disclosure. Accordingly, other implementations are within the scope of the following claims.

What is claimed is:

1. A printed circuit board for transmission control and for arrangement on an interface, the printed circuit board comprising:
an upper side;
an underside arranged at a distance from the upper side; and
a plurality of spaced-apart conductor tracks positioned between the upper side and the underside, the plurality of spaced-apart conductor tracks are connected to each other in an electrically conductive manner by way of a first plated-through hole,
wherein the first plated-through hole is drilled out on the underside of the printed circuit board in such a way that it is arranged so as to be set back in relation to the underside of the printed circuit board, and
wherein the printed circuit board is arranged on an interface, the underside of the printed circuit board facing the interface.

2. The printed circuit board as claimed in claim 1, wherein a second plated-through hole is made to extend to the underside of the printed circuit board and/or has a protrusion in relation to the underside of the printed circuit board, wherein the second plated-through hole is connected in an electrically conductive manner to a ground layer arranged within the printed circuit board.

3. The printed circuit board as claimed in claim 2, wherein the second plated-through hole has a solder resist layer between the underside of the printed circuit board and/or the protrusion in relation to the underside of the printed circuit board and the interface.

4. The printed circuit board as claimed in claim 2, wherein the first plated-through hole and/or the second plated-through hole are each formed as a sleeve.

5. The printed circuit board as claimed in claim 4, wherein the sleeve is potted with a resin.

6. The printed circuit board as claimed in claim 1, wherein the conductor tracks and/or the first plated-through hole and/or the second plated-through hole are formed from copper or at least comprise copper.

7. The printed circuit board as claimed in claim 1, wherein the printed circuit board can be arranged on the interface in a form-fitting, material-bonding and/or force-fitting manner.

8. The printed circuit board as claimed in claim 1, wherein the interface is a hydraulic block of a transmission.

9. A transmission control apparatus for a motor vehicle, the transmission control apparatus comprising:
a printed circuit board including:
an upper side;
an underside arranged at a distance from the upper side;
a first plated-through hole drilled out on the underside of the printed circuit board in such a way that it is arranged so as to be set back in relation to the underside of the printed circuit board;
a plurality of spaced-apart conductor tracks connected to each other in an electrically conductive manner by way of the first plated-through hole;
an interface supporting the printed circuit board, the underside of the printed circuit board facing the interface.

10. The transmission control apparatus as claimed in claim 9, wherein the printed circuit board further comprises:
a second plated-through hole extending to the underside of the printed circuit board and/or has a protrusion in relation to the underside of the printed circuit board,
a ground layer wherein the second plated-through hole is connected in an electrically conductive manner to the ground layer.

11. The transmission control apparatus as claimed in claim 10, wherein the second plated-through hole has a solder resist layer between the underside of the printed circuit board and/or the protrusion in relation to the underside of the printed circuit board and the interface.

12. The transmission control apparatus as claimed in claim 10, wherein the first plated-through hole and/or the second plated-through hole are each formed as a sleeve.

13. The transmission control apparatus as claimed in claim 12, wherein the sleeve is potted with a resin.

14. The transmission control apparatus as claimed in claim 9, wherein the conductor tracks and/or the first plated-through hole and/or the second plated-through hole are formed from copper or at least comprise copper.

15. The transmission control apparatus as claimed in claim 9, wherein the printed circuit board is arranged on the interface in a form-fitting, material-bonding and/or force-fitting manner.

16. The transmission control apparatus as claimed in claim 9, wherein the interface is a hydraulic block of a transmission.
